(19) United States
(12) Patent Application Publication
(10) Pub. No.: US 2026/0238608 A1
(43) Pub. Date: Aug. 13, 2026

(54) METHODS AND SYSTEMS FOR ENCODING AND PROBABILISTICALLY DECODING DATA

(71) Applicant: Open Cybernetics LLC, Cheyenne, WY (US)

(72) Inventor: Lum Ramabaja, Cheyenne, WY (US)

(21) Appl. No.: 19/049,223

(22) Filed: Feb. 10, 2025

(51) Int. Cl. H04L 51/066; H03M 13/00; H03M 13/37

(52) U.S. Cl. CPC H04L 51/066; H03M 13/3746; H03M 13/6572

(57) ABSTRACT

Disclosed is a method for receiving an input data comprising source symbols (SS); initializing an encoded sequence(ES) to an empty state; initializing chain header(s) (CH(s)) by setting value of CH to nonce; iteratively encoding each SS sequentially to generate ES, by: updating CH, based on preceding CH and current SS; generating an encoded symbol for each SS; and updating state of ES by storing encoded symbol to ES at given index position; generating final CH after iterative encoding of SS; transmitting ES, and final CH; and decoding ES by: reconstructing candidate SS sequences through probabilistic traversal of potential decoding paths in multi-branch decoding tree; and determining correct decoding path by iteratively pruning invalid decoding paths based on at least predefined probabilistic rules, wherein correct decoding path comprises candidate SS sequence that aligns with SSs and produces final CH of the ES.

### TECHNICAL FIELD

The present disclosure relates to methods for encoding and probabilistically decoding data. The present disclosure relates to systems for encoding and probabilistically decoding data.

### BACKGROUND

Information chaining is a novel family of algorithms designed to enhance reliability and efficiency in data transmission and storage systems. These algorithms leverage dependencies between encoded symbols to create advanced erasure codes, forward error correction (FEC) codes, and state-of-the-art fountain codes. By introducing probabilistic relationships between symbols, information chaining enables robust data reconstruction even in the presence of losses or errors during transmission or storage.

A major challenge in modern data systems is ensuring reliable data recovery in scenarios with unpredictable packet losses, high network churn, or limited storage capacity. Traditional data redundancy methods like replication impose high bandwidth and storage overhead, while connection-oriented protocols such as TCP introduce significant latency. Moreover, existing error correction schemes often face inefficiencies in handling burst errors and variable loss rates, limiting their adaptability to real-world network conditions.

Information chaining addresses these challenges by encoding data into sequences of symbols that are probabilistically linked, enabling efficient recovery of lost or corrupted symbols. Techniques such as probabilistic binary chaining introduce conditional dependencies between encoded symbols, facilitating accurate reconstruction of the original data even when some encoded symbols are missing. Additionally, by adjusting parameters like code rate and redundancy, information chaining algorithms provide flexibility to adapt to various loss scenarios while maintaining computational efficiency.

While information chaining introduces significant advancements, challenges remain in optimizing its performance for diverse real-world applications. The probabilistic nature of the decoding process can result in false positive matches, leading to an increase in computational complexity due to the need to prune invalid decoding paths. This is because the false positive matches can occur even in the presence of symbols, unlike in other variants such as collision-free information chaining, where branches form only when a symbol is missing.

Furthermore, achieving a balance between code overhead and decoding efficiency requires careful tuning of parameters, which may not always be straightforward. Contrary to a notion that predefined probabilistic rules for pruning and branching conditions limit adaptability to varying error distributions, practical implementations, such as those in fountain codes, allow for dynamic adjustments. In these systems, a message is divided into separate blocks, each of which is independently encoded. If the error distribution changes, the offset value (m) of a block can be modified, enabling the system to adapt to shifting loss distributions effectively.

### SUMMARY

The aim of the present disclosure is to provide a method for encoding and probabilistically decoding data, and system for encoding and probabilistically decoding data ensures efficient and reliable data reconstruction by maintaining symbol dependencies during encoding and leveraging probabilistic traversal and pruning during decoding to handle errors and data loss effectively. The aim of the present disclosure is achieved by a method for encoding and probabilistically decoding data, and a system for encoding and probabilistically decoding data, as defined in the appended independent claims to which reference is made to. Advantageous features are set out in the appended dependent claims.

Throughout the description and claims of this specification, the words “comprise”, “include”, “have”, and “contain” and variations of these words, for example “comprising” and “comprises”, mean “including but not limited to”, and do not exclude other components, items, integers or steps not explicitly disclosed also to be present. Moreover, the singular encompasses the plural unless the context otherwise requires. In particular, where the indefinite article is used, the specification is to be understood as contemplating plurality as well as singularity, unless the context requires otherwise.

### BRIEF DESCRIPTION OF THE DRAWINGS

FIG. 1 illustrates is a flowchart depicting steps of a method for encoding and probabilistically decoding data, in accordance with an embodiment of the present disclosure;

FIG. 2A illustrates a decoding process of a multi-branch encoding tree comprising a binary tree, in accordance with an embodiment of the present disclosure;

FIG. 2B illustrates a decoding process of the binary tree 202 due to false positives, in accordance with an embodiment of the present disclosure;

FIG. 3 illustrates a graphical representation of a relationship between code overhead, expected number of lead nodes, and a length of input data, in accordance with an embodiment of the present disclosure;

FIG. 4 illustrates a depiction of wrong branches for a given correct path of FIG. 2A, in accordance with an embodiment of the present disclosure;

FIGS. 5A and 5B illustrate a depiction of wrong branches for a given correct decoding path of a binary tree of FIG. 2A, in accordance with an embodiment of the present disclosure;

FIG. 6 is a graphical representation of a relationship between various code overheads, expected number of leaf nodes and length of the input data, in accordance with an embodiment of the present disclosure;

FIG. 7 shows a sequential diagram for erasure in encoded sequence, in accordance with an embodiment of the present disclosure; and

FIG. 8 illustrates a block diagram of a system for encoding and probabilistically decoding data, in accordance with an embodiment of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

In a first aspect, the present disclosure provides a method for encoding and probabilistically decoding data, the method comprising:
receiving an input data comprising a plurality of source symbols, wherein each source symbol represents a binary value or a multi-bit value;
initializing an encoded sequence to an empty state;
initializing at least one chain header by setting a value of the at least one chain header to a nonce;
iteratively encoding each source symbol sequentially from amongst the plurality of source symbols to generate the encoded sequence, by:
   updating the at least one chain header, based on a preceding chain header and a current source symbol;
   generating an encoded symbol for each source symbol, based on the updated chain header, wherein the encoded symbol represents a binary value or a multi-bit value; and
   updating a state of the encoded sequence by storing the encoded symbol at a given index position within the encoded sequence, wherein the encoded sequence is initialized with unassigned values;
generating a final chain header after iterative encoding of all source symbols in the plurality of source symbols;
transmitting the encoded sequence, and the final chain header; and
decoding the encoded sequence by:
   reconstructing candidate source symbol sequences through probabilistic traversal of potential decoding paths in a multi-branch decoding tree, wherein each node corresponds to the given source symbol; and
   determining a correct decoding path from amongst a plurality of decoding paths by iteratively pruning invalid decoding paths, based on at least predefined probabilistic rules,
   wherein the correct decoding path comprises the candidate source symbol sequence that aligns with the plurality of source symbols and produces a final chain header that matches the final chain header of the encoding sequence.

In a second aspect, the present disclosure provides a system for encoding and probabilistically decoding data, the system comprising at least one processor configured to:
receive an input data comprising a plurality of source symbols, wherein each source symbol represents a binary value or a multi-bit value;
initialize an encoded sequence to an empty state;
initialize at least one chain header by setting a value of the at least one chain header to a nonce;
iteratively encode each source symbol sequentially from amongst the plurality of source symbols to generate the encoded sequence, by:
   updating the at least one chain header, based on a preceding chain header and a current source symbol;
   generating an encoded symbol for each source symbol, based on the updated chain header, wherein the encoded symbol represents a binary value or a multi-bit value; and
   updating a state of the encoded sequence by storing the encoded symbol at a given index position within the encoded sequence, wherein the encoded sequence is initialized with unassigned values;
generate a final chain header after iterative encoding of all source symbols in the plurality of source symbols;
transmit the encoded sequence, and the final chain header; and
decode the encoded sequence by:
   reconstructing candidate source symbol sequences through probabilistic traversal of potential decoding paths in a multi-branch decoding tree, wherein each node corresponds to the given source symbol; and
   determining a correct decoding path from amongst a plurality of decoding paths by iteratively pruning invalid decoding paths, based on at least predefined probabilistic rules,
   wherein the correct decoding path comprises the candidate source symbol sequence that aligns with the plurality of source symbols and produces a final chain header that matches the final chain header of the encoding sequence.

The aforementioned first aspect and the second aspect provides an efficient and reliable data transmission and reconstruction. By iteratively updating the at least one chain header and encoding each source symbol in a sequential manner, the method ensures that the encoded sequence and the at least one chain header maintain dependencies that facilitate error detection and correction. The multi-branch decoding tree, coupled with probabilistic traversal and pruning of invalid paths, significantly reduces computational overhead by iteratively narrowing down the decoding possibilities to converge on the correct path. This approach provides robust performance even under conditions of data loss or noise, as it leverages predefined probabilistic rules to maintain accuracy. Furthermore, the use of a final chain header as a verification mechanism enhances the fidelity of the reconstructed data, ensuring alignment with the original source symbols. This systematic encoding and decoding process delivers a balance between computational efficiency, scalability, and reliability, which is particularly beneficial in storage and transmission systems with high error or erasure rates. Moreover, a lineage of potential paths refers to how the dependency between successive encoded symbols ensures that wrong paths terminate, reducing computational overhead. The goal is to efficiently converge to the correct decoding path by leveraging probabilistic dependencies, ensuring that only paths consistent with the encoded sequence and at least one chain header remain viable. For sake of brevity, hereinafter the term “at least one chain header” is used interchangeably with the term “chain header”.

Throughout the present disclosure, term “input data” refers to raw information that is transformed to the encoded sequence, and is subsequently probabilistically decoded. The input data is received from a communication interface, for example, such as a communication channel, a storage medium, a user device, and similar. The input data is received in a format that enables accessing and processing individual source symbols sequentially or in parallel. Moreover, the term “source symbol” refers to the smallest indivisible unit of data in the input data that carries meaningful information for encoding. When each source symbol represents the binary value, it indicates that each source symbol could be a single bit, i.e., either 0 or 1. When the source symbol represents the multi-bit value, it indicates that each source symbol could include multiple bits (for example, such as 4-bit, 8-bit words, or higher-order symbols), which generalizes encoding and decoding to handle the plurality of source symbols (namely, n source symbols, wherein n represents a number of bits in the input data) beyond binary values. Hence, the input data is received in such a structured form as information chaining operates on the plurality of source symbols, wherein each symbol is iteratively encoded to form a probabilistic linkage across the encoded sequence. In an implementation, when each source symbol represents the binary value (in other words, an implementation that work on individual bits), it is determined d to be binary information chaining. In another implementation, when each source symbol represents the multi-bit value, it is determined to be symbol information chaining.

Optionally, the multi-bit value comprises a byte. In this regard, the input data is represented as a group of 8 bits. Herein, the byte can represent 256 distinct values (i.e., from 0 to 255 in unsigned representation). The byte allows representation of numerical characters, alphabetic characters, alphanumeric characters (for example, such as ASCII, UTF-8). Moreover, the byte is treated as a single unit for storage, processing, and transmission. During encoding, each byte is extracted from the input data and processed sequentially or parallelly to generate the encoded sequence. A technical effect of the multi-bit comprising the byte is that it allows efficient processing of large data sets while maintaining error correction and redundancy mechanism.

Throughout the present disclosure, the term “encoded sequence” refers to an output structure that stores each encoded symbol from respective source symbol while encoding. The encoded sequence is initialized to the unassigned values, wherein memory is allocated for the encoded sequence without populating it with any encoded symbols initially. This is typically achieved by creating a data structure (for example, such as an array, a buffer) with either a predefined size or a dynamic capacity. The data structure is set to an unassigned state to prepare it for sequential updates when encoding. Such initialization of the encoded sequence ensures that the encoded sequence is ready to receive each encoded symbol as it is generated. Beneficially, initialization to an empty state allows the encoded sequence to accommodate data of varying sizes without disruption to the encoding process.

Throughout the present disclosure, the term “chain header” refers to a state variable that maintains dependencies across encoded symbols (namely, n′ encoded symbols, wherein n′ represents a number of bits in the encoded sequence) during the encoding and decoding processes. The chain header is updated iteratively to reflect a current status of encoding the plurality of source symbols. Moreover, the term “nonce” refers to a unique and a non-repeating value that serves as an initial state of the chain header. The value of the chain header is set to the nonce to ensure that the initial state of the chain header is distinct for encoding, i.e., the nonce is a seed value. Moreover, the nonce can be either randomly initialized, set to a predetermined initial value (for example, such as zero), or set via any other heuristic. The chain header, initialized by the nonce, determines a transformation or linkage of each source symbol in a probabilistic manner. This ensures that a state of each source symbol depends on preceding source symbol.

Optionally, the nonce comprises at least one of: an empty state, a counter, a random number, a random number generated via a public key. A technical effect of the aforementioned feature is that by allowing diverse initialization mechanisms, wherein the encoding and decoding can be scaled to different application domains, from basic data processing to high-security environments. When the nonce comprises the empty state, it means that the chain header is initialized to a default or zero-like value that signifies the unassigned state. When the nonce comprises the counter, a monotonically increasing or cyclic counter value is assigned to the chain header to ensure sequential uniqueness. When the nonce comprises the random number, a pseudo-random or cryptographically secure random value is generated and assigned to the chain header to provide unpredictability. When the nonce comprises the random number generated via the public key, a cryptographically secure random value is generated using a public key mechanism, ensuring both uniqueness and security by leveraging asymmetric cryptographic operations. Optionally, when the nonce comprises a non-zero value, a separate chain header is computed to create redundant symbols, otherwise mappings of the different redundant symbols would be same.

Each source symbol from amongst the plurality of source symbols are processed in a sequential manner, one at a time, to generate the encoded sequence. The encoding of each source symbol ensures that dependencies are maintained across the encoded sequence. Such iterative processing allows each encoded symbol to depend on the current source symbol and the chain header, thus capturing relationships between consecutive source symbols from amongst the plurality of source symbols. Moreover, encoding each source symbol in a sequential manner ensures that the encoded sequence aligns with original data structure of the input data.

In this regard, during encoding, the input data is transformed in a way that links probabilities of each of the plurality of source symbols in a linear manner. In other words, after transformation, the source symbols of the input data are not independent anymore. Beneficially, even if some of the encoded symbols are erased or flipped, it is still possible to retrieve the input data. For sake of brevity, hereinafter, an array of the encoded symbols after applying information chaining is used interchangeably with the term “code”.

The chain header is updated by applying a predefined function (for example, such as a state update function) that combines the preceding chain header and the current source symbol. In other words, the predefined function computes a new state of the chain header that incorporates the preceding chain header and the current source symbol. Such computation of the new state of the chain header updates said chain header, wherein the chain header currently represents a new state for subsequent operations while encoding each of the plurality of source symbols. Herein, the “preceding chain header” refers to a chain header's value before processing the current source symbol, which represents a state accumulated from previously processed source symbols. Moreover, the term “current source symbol” refers to a source symbol that is being processed in current iteration, which influences the update to the chain header.

Optionally, the at least one chain header is updated by at least one of: a hash function, a random number generator, a mathematical function, a Boolean operation, a cryptographic technique, a linear transformation, a state transition based on a given source symbol from amongst the plurality of source symbols, a neural network model. A technical effect of updating the chain header in an iterative manner using different methods is that accurate reconstruction of each of the plurality of source symbols.

When the chain header is updated using the hash function, a deterministic algorithm is used to compute a fixed-size hash value based on the preceding chain and the current source symbol. When the chain header is updated using the random number generator, a pseudo-random or cryptographically secure random number is generated and combined with the chain header to introduce controlled randomness. When the chain header is updated using the mathematical function, arithmetic or algebraic operations (for example, such as modular arithmetic, exponential functions) are applied to calculate the updated chain header. When the chain header is updated using the Boolean operation, bitwise logical operations (e.g., XOR, AND, OR) are used to update the chain header efficiently. When the chain header is updated using the cryptographic technique, encryption or hashing methods (for example, such as Advanced Encryption Standard (AES), Secure Hash Algorithm (SHA)) provide secure state updates to prevent unauthorized interference. When the chain header is updated using the linear transformation, matrix operations or linear algebraic transformations update the chain header in systems requiring high-dimensional state representation. When the chain header is updated using the state transition based on a given source symbol from amongst the plurality of source symbols, a finite state machine dynamically adjusts the chain header based on transitions defined by the current source symbol. When the chain header is updated using the neural network model (for example, such as Recurrent Neural Network (RNN)), a trained neural network processes the preceding chain header and the current source symbol to produce the updated state, leveraging learned relationships for complex transformations.

For each source symbol in the plurality of source symbols, the corresponding updated chain header is retrieved after it has been iteratively modified to reflect dependencies on prior source symbols. The encoded symbol for each source symbol is generated by using a predefined encoding function. Examples of the predefined encoding function may include, but are not limited to, mathematical operations, probabilistic rules, and deterministic transformations. The generated encoded symbol is either a binary value (a single bit) or a multi-bit value (e.g., an 8-bit or 16-bit representation). This process is repeated iteratively for each source symbol to generate a complete encoded sequence. Moreover, generating the encoded symbols based on the updated chain header ensures that each symbol reflects the cumulative influence of preceding source symbols. This dependency facilitates error correction and decoding. Additionally, encoding each of the plurality of source symbols based on the updated chain header ensures that decoding of the encoded sequence can accurately reconstruct the plurality of source symbols by leveraging the same dependencies.

The encoded sequence is pre-allocated as a fixed-size array, wherein the encoded sequence is initialized with unassigned values (for example, such as nulls, zeros, placeholders). Moreover, the given index position within the encoded sequence is determined based on the iteration count or the position of the corresponding source symbol in the input sequence. The encoded symbol, generated for the current source symbol, is stored at the given index position within the encoded sequence. This ensures that each encoded symbol is sequentially placed in its corresponding position. Additionally, storing the encoded symbols at the given index position ensures that the encoded sequence aligns with the original order of each of the plurality of source symbols, thus enabling accurate decoding. Herein, the term “index position” refers to a location within the encoded sequence where the current encoded symbol is stored, corresponding to the position of the associated source symbol in the input data.

Subsequently, after encoding, the input data is transformed from a state of n source symbols to another state of n′ encoded symbols, wherein the state of n source symbols is less than the other state of n′ encoded symbols, i.e., n<n′. Moreover, a relationship between the n source symbols and the n′ encoded symbols is given by a code rate, wherein the code rate is a measure of the proportion of data in the encoded sequence that represents the original source symbols without redundancy. An exemplary mathematical formula for the code rate is given by equation (1),

$$Code rate = \frac{Number of source symbols}{Total Number of encoded symbols}$$

wherein the fraction quantifies how much of the encoded sequence consists of useful, non-redundant data. In this regard, the code rate, therefore, directly impacts the balance between redundancy and efficiency. Herein, a high code rate (i.e., closer to 1) implies minimal redundancy, which is efficient but less resilient to errors. Moreover, a low code rate (closer to 0) indicates substantial redundancy, enhancing resilience but increasing overhead.

Optionally, depending on the application, the encoded symbols lie in a range of 0.3 percent to 100 percent of a total number of the plurality of source symbols. The encoded symbols may, for example, lie in a range of 0.3, 0.5, 1.0, 10, 30, 55, or 90 percent of the total number of the plurality of source symbols to 0.4, 5, 20, 45, 65, 80, 90, 95, 98, or 100 percent of the total number of the plurality of source symbols. As an example, for storage or transmission applications, the n′ encoded symbols may be tuned to be 0.5 percent larger than n source symbols. As another example, for error correcting applications, the n′ encoded symbols may be tuned to be 100% larger n source symbols.

In a first example, there may be a prototype algorithm for encoding an input data of source symbols S into encoded symbols E. Herein, the algorithm comprises an encoding function, that takes an input of source symbols S and a nonce. The nonce may be used as a seed during information chaining procedure. Herein, since the algorithm may utilize only a single chain with a 2× overhead, the nonce may be assigned an empty state. In this regard, a 2× overhead means that for every source symbol (i.e. bit) in the input data, corresponding encoded symbol in the encoded sequence may contain two bits. Herein, the code rate maybe

$$\frac{\vert S \vert}{\vert E \vert} = 1 .$$

Within the encoder function, an empty code may be defined, along with assigning the nonce to the chain header. Subsequently, there may be iteration over every source symbol sᵢ within the input data, with a goal of populating the code with the corresponding encoded symbol. This may be achieved by first updating the chain header, so as to assign to the chain header a random value that is generated from the previous chain header and current source symbol. Thereafter, a random bit may be assigned to every e_{i,0} and e_{i,1}. Herein, a state of e_{i,0} and e_{i,1} may be dependent on the previous states. In this regard, a sequential dependency may be realized through the chain header. In the algorithm, e_{i,0} may take a value of rightmost bit (namely, least significant bit (LSB)) within the chain header, and e_{i,1} may take a value of second LSB. The two bits may be then appended to the code. The bit values of e_{i,0} and e_{i,1}, together denoted as simply eᵢ, that may represent the encoded symbol for a given source symbol. Hence, a random value for e₂ depends on s₂, s₁ and on so. The random value for e₁ depends on sᵢ and so, and so on. Finally, the code may be returned as well as the final chain header. This prototype algorithm may be provided by an exemplary algorithm (i.e., Algorithm 1) and a rust example (i.e., Rust Example 1) in the APPENDIX.

Optionally, at the step of iteratively encoding each source symbol sequentially from amongst the plurality of source symbols to generate an encoded sequence, the method further comprises recurringly appending a redundant symbol at an interval of at least one encoded symbol comprised in the encoded sequence. In this regard, at each step of iteratively encoding a source symbol from the plurality of source symbols, a redundant symbol is appended to the encoded sequence at intervals (denoted by m and/or m-value). This process begins by determining whether the current encoding position aligns with the interval. When the current encoding position aligns with the interval, the redundant symbol is generated and appended to the encoded sequence, wherein the redundant symbol could be derived from the encoded symbols or the updated chain header. This operation is repeated throughout the encoding process, ensuring that redundancy is consistently added at systematically at the intervals. It will be appreciated that the interval comprises any one of: a predefined value, a dynamic value. When the interval comprises the predefined value, it means that the interval is a fixed value, for example, such as m=1,2,3, and so forth, wherein the fixed value is hardcoded in the algorithm settings. When the interval comprises the dynamic value, it means that the interval is based on at least one characteristic (for example, such as a size) of the input data. Moreover, the m-value is defined as a parameter and depends on various applications. For example, if packet loss rate is expected to be high, then there is a requirement for smaller m-value (because a smaller m leads to more bits of encoded symbols, i.e. a higher overhead). If the packet drop rate is expected to be low, then there is a requirement of large m-values (for example, m=40 means that the encoded sequence will be 2.5 percent larger than the input data, meaning that it can tolerate up to 2.5 percent of total packet drops).

A technical effect of recurringly appending the redundant symbol in such a manner is that it improves a reliability and an accuracy of decoding the encoded sequence by enabling error detection and correction, ensuring robust recovery of each of the plurality of source symbols.

It will be appreciated that the redundant symbol need not be assigned to every encoded symbol of the encoded sequence. There can also be encoded symbols that use only one bit, and assign an additional redundant bit to every interval (i.e., m-th) of the encoded symbol. For example, considering a binary tree where there is a depiction of wrong branches for a given correct decoding path. Instead of assigning two bits to every encoded symbol, the redundant bit may be assigned only to every second encoded symbol (i.e., m=2), thus effectively decreasing the code overhead from 2× to 33.3 percent. Similarly, the redundant bit may be assigned only to every third encoded symbol (i.e., m=3), thus effectively decreasing the code overhead from 33.3 percent to 24.99 percent.

Throughout the present disclosure, the term “final chain header” refers to a chain header that reflects a cumulative state of all iterations. The final chain header is then stored or retained as a reference for decoding the encoded sequence.

The encoded sequence and the final chain header are transmitted over a communication channel to a receiver. The communication channel may be wired, wireless, and/or optical communication channel. During such transmission, it is ensured that the encoded sequence and the final chain header are delivered to the receiver. Notably, codes based on information chaining, being forward error correction codes, do not require reliable transmission. If some packets are lost, it means that some encoded symbols have been erased. Beneficially, the present methodology can still reliably decode the encoded sequence even if some of the encoded symbols were erased. Herein, both the encoded sequence and the final chain header are organized into a transmission format, for example, such as packets or frames, depending on a communication protocol of the communication channel.

Throughout the present disclosure, the term “candidate source symbol sequence” refers to a hypothetical reconstruction of original plurality of source symbols from the encoded sequence. The candidate source symbol sequences represent a potential arrangement of each of the plurality of source symbols that, if encoded, could generate the encoded sequence. During decoding, multiple candidate sequences are evaluated to identify the correct one that aligns with the original source symbols. Moreover, the term “multi-branch decoding tree” refers to a hierarchical structure, wherein a root node corresponds to an initial state of the chain header, each level of the multi-branch decoding tree represents a given source symbol's position in the encoded sequence, and branches at each level represent possible source symbols for that position. Moreover, the term “probabilistic travel” refers to a process of exploring the multi-branch decoding tree, where each branch represents a potential source symbol, and predefined probabilistic rules guide the traversal. Herein, the probabilistic traversal follows the predefined probabilistic rules (for example, such as comparing candidate encoded symbols with the actual encoded sequence) to build candidate source symbol sequences, path by path. At each step, the probabilistic traversal adds the current node's symbol to the candidate sequence being reconstructed to create a potential decoding path. Herein, the term “potential decoding path” refers to a specific sequence of nodes in the multi-branch decoding tree, that represents a series of candidate source symbols corresponding to consecutive positions in the encoded sequence.

Once the candidate source symbol sequences are reconstructed, the correct decoding path is identified by iteratively pruning invalid decoding paths. Herein, the term “correct decoding path” refers to a unique path that reconstructs the plurality of source symbols accurately and produces the final chain header that matches the final chain header in the encoded sequence. Moreover, the term “invalid decoding paths” refers to those decoding paths that deviate from the encoded sequence or fail to meet the predefined probabilistic rules. The predefined probabilistic rules are applied to each decoding path of the candidate source symbol sequences, thus evaluating a validity of each decoding path based on alignment with the encoded sequence and its ability to produce a valid chain header. Moreover, at least one decoding path from amongst the plurality of decoding paths that fail are pruned, thus reducing a number of potential decoding paths. This iterative process continues until only the correct decoding path remains, characterized by the candidate source symbol sequence that aligns with the original plurality of source symbols and produces a chain header matching the final chain header. For example, on an average 50 percent wrong paths of the total number of potential decoding paths may get pruned per iteration. Moreover, new decoding paths may also be formed every iteration, even in the absence of erasures. The oscillatory behavior for when the internal is greater than 1 (as described later) happens because at redundant symbols on average more decoding paths get pruned than created.

Optionally, the method further comprises:
determining an expected number of invalid decoding paths, wherein the expected number of invalid decoding paths provides an estimate of how many invalid decoding paths is encountered at a given depth; and
using the expected number of invalid decoding paths for pruning the invalid coding paths while maintaining at least one candidate decoding path to converge towards the correct decoding path.

In this regard, when m>1, an expected number of invalid decoding paths (namely, an expected number of leaf nodes) does not gradually converge to a given value like for m=1, but converges to an oscillation with m being the upper bound of the oscillation. The oscillating behavior occurs due to an amount of information within each encoded symbol. The encoded symbols with no redundant symbols will have an expected number of leaf nodes during decoding that grows linearly with the distance traversed. But every time the encoded symbol with a redundant symbol is reached, approximately half the branches within the binary tree get pruned, i.e. reach a dead-end. The process of growth then repeats until an encoded symbol with a redundant symbol is reached again.

Optionally, the multi-branch decoding tree comprises a binary tree, the step of decoding emulates a breadth-first traversal of the binary tree, wherein the binary tree is characterized by:
a root initialized with a nonce as the at least one chain header;
a depth corresponding to a length of the input data, wherein each level of the depth represents a bit index position of each source symbol from amongst the plurality of source symbols;
a branching condition to grow the binary tree iteratively, wherein the branching condition is determined when a predefined probabilistic criterion for branching at a given bit index position is met, wherein the predefined probabilistic criterion is satisfied when a value of a candidate symbol in the candidate symbol sequence produces a candidate encoded symbol that matches a corresponding encoding symbol of the ended sequence; and a plurality of branches based on false positive matches, wherein each of the plurality of branches is pruned iteratively during traversal to converge towards the correct decoding path.

In this regard, the multi-branch decoding tree comprises a binary tree when binary information chaining is performed. Alternatively, in an instance of symbol information chaining (for example, when a symbol comprises 8 bits), a node in the multi-branch decoding tree can have up to 256 children. Moreover, the root node of the binary tree is initialized with a nonce, which serves as the initial state of the chain header. The depth of the binary tree corresponds to the length of the input data, where each level represents a bit index position for the source symbols in the sequence. At each level of the binary tree, a branching condition determines whether to generate branches for candidate symbols (for example, such as binary values 0 and 1). This branching condition is evaluated probabilistically based on whether a candidate encoded symbol, derived from the candidate source symbol, aligns with the corresponding source symbol in the encoded sequence.

Moreover, the decoding process emulates the breadth-first traversal of the binary tree, exploring all nodes at a given level before moving to the next level. This ensures that potential decoding paths are considered systematically. The plurality of branches that result from false positive matches are iteratively pruned during traversal. This pruning eliminates those decoding paths that do not satisfy the predefined probabilistic criterion for branching or fail to align with the encoded sequence. Herein, the term “predefined probabilistic criterion” refers to rules or conditions that determine whether a candidate symbol of the binary tree is valid. A technical effect of the multi-branch decoding tree comprising the binary tree is that it ensures reliable reconstruction of source symbols by maintaining alignment with the encoded sequence, pruning invalid paths, and balancing computational efficiency with decoding accuracy.

Optionally, the false positive match comprises a decoding path from amongst the plurality of decoding paths that appears present during the step of decoding the encoded sequence, but was not utilized at the step of iteratively encoding each source symbol sequentially from amongst the plurality of source symbols to generate the corresponding encoded symbol in the encoded sequence. A technical effect of the aforementioned feature is that such false positive matches temporarily introduce additional decoding paths, ensuring comprehensive exploration of potential sequences, while iterative pruning effectively eliminates invalid paths, enabling accurate and efficient reconstruction of the source symbols.

In this regard, at each step of decoding, candidate decoding paths are evaluated against the encoded sequence. This involves checking whether the current candidate decoding path, when processed, produces a source symbol that aligns with the corresponding encoded symbol. The false positive match arises when a decoding path appears valid (i.e., aligns with the encoded sequence probabilistically) but was not actually utilized during the original encoding process. Such false positive matches contribute to additional branches in the decoding tree, which are iteratively pruned based on predefined probabilistic criteria to eliminate invalid paths.

In a second example, with reference to the first example, there may be an algorithm for decoding the encoded sequence. Herein, a goal during decoding may be to iteratively figure out in a computationally efficient way the source symbol that was used to create a given encoded symbol. A symbol set may be used for decoding that comprises only two symbols—zero and one. With reference to example 1, every encoded symbol may comprise two bits, wherein eᵢ₀ represents the first bit of the encoded symbol eᵢ, and eᵢ₁ represents the second bit of eᵢ. Herein, the probabilistic traversal may be a breadth-first traversal, when the multi-branch encoding tree comprises the binary tree. For each potential decoding path within the binary tree, it may be determined whether one of the symbols within the symbol set, could be used to recreate eᵢ. This may be achieved by computing the new chain header just as in the encoding step, and then computing the encoded symbol (e′_{i,0} and e′_{i,1}) by using one of the potential source symbols s′ from the symbol set. Subsequently, the branching condition may be e′_{i,0}=e_{i,0} Λe′_{i,1}=e_{i,1} which returns TRUE. If one of the potential source symbols from the symbol set fulfils the branching condition, the potential source symbols and the derived chain header are saved as potential candidates. The chain header may be used as an identifier for the decoding path.

Optionally, the plurality of decoding paths lies in a range of a total number of the plurality of source symbols to an exponential function of two with an exponent of the total number of the plurality of source symbols. In this regard, at the beginning of decoding the encoded sequence, a number of decoding paths corresponds to the total number of source symbols in the sequence, as each source symbol contributes one path initially. As the multi-branch decoding tree is traversed, branching occurs at each level. In an instance, each source symbol from amongst the plurality of source symbols contributes to potential branches, with each node potentially splitting into two branches, when the plurality of source symbols represent the binary values. In another instance, each source symbol from amongst the plurality of source symbols contributes to potential branches, with each node potentially splitting into 256 branches, when the plurality of source symbols represent multi-bit values (for example, such as bytes).

Moreover, the total number of potential decoding paths is bounded by an exponential function of base two, where the exponent equals the total number of source symbols. This exponential growth reflects the maximum number of paths that could theoretically be generated if all branches are followed without pruning. Hence, the lower bound of the range corresponds to the number of the plurality of source symbols, while the upper bound is 2″, where n is the total number of source symbols. This range encapsulates the potential growth in the number of decoding paths during the traversal of the multi-branch decoding tree. A technical effect of this range of the decoding paths is that it ensures that decoding the encoded sequence balances computational feasibility and completeness, enabling efficient pruning of invalid paths while retaining all valid candidates for accurate reconstruction of each of the plurality of source symbols.

Optionally, a probability of the correct decoding path being identified lies is based on the false positive rate, and a probability of the invalid decoding path being selected is based on the interval of the at least one encoded symbol. The probability of a decoding path (that has been inserted into the multi-branch encoding tree comprising the binary tree) to appear present during the decoding could be 1.0. In other words, if a decoding path was used to create eᵢ during encoding, then checking for the presence of that decoding path during decoding will always return true. Alternatively, when a decoding path that was not used to create eᵢ during encoding is checked, then the decoding path can still appear as if present during decoding. That is, there are false positive matches during decoding.

A technical effect of the relationship between the probability of identifying the correct decoding path and the false positive rate, combined with the dependency of selecting an invalid decoding path on the interval of the at least one encoded symbol, is that it ensures a balanced trade-off between at least one of: overhead and computational efficiency, memory complexity and time complexity, enabling optimized path pruning and robust data reconstruction.

Continuing in reference to the first and the second examples, when the multi-branch encoding tree comprises the binary tree, there may be 2× overhead. In other words, there may be a 25 percent chance for the candidate decoding path to appear present during decoding, even if it was not inserted during encoding. In other words, the false positive rate for a lookup may be p=0.25. When the plurality of source symbols represents the binary value, that means that each of the plurality of source symbols comprise a single bit, that is either zero or one. This means that there may be only two possible states for each of the plurality of source symbols. Meanwhile, the encoded symbols may have four possible states, 00, 01, 10 and 11, as there are two bits per encoded symbol. While there may be a ½ probability for a false positive when checking one bit of the encoded symbol, checking two bits per encoded symbol intuitively has a ¼ probability, meaning that there may be a 25 percent chance. Due to the false positive hits, instead of having a single decoding path across the binary tree representing the input data, other branches may be encountered during decoding. Herein, a goal during decoding is to find in an efficient way the correct decoding path within the binary tree out of the 2ⁿ possible paths. Since the mapping of the source symbol onto the code depends on all the preceding source symbols, the probabilities of wrong branches (or, invalid branches) during decoding are not independent anymore.

Optionally, a rate of the false positive matches for consecutive candidate source symbol in the candidate source symbol sequence that forms the invalid decoding path is an exponential function, wherein a base of the exponential function corresponds to a false positive rate and an exponent corresponds to a length of the invalid decoding path within the binary tree. A technical effect of the exponential relationship between the false positive rate and the length of an invalid decoding path ensures that longer invalid paths are increasingly unlikely, facilitating efficient pruning and accurate decoding in the binary tree structure.

In this regard, a base value is established for the false positive rate, representing the probability of a single candidate source symbol being incorrectly accepted during decoding. Subsequently, for consecutive candidate symbols in an invalid decoding path, the cumulative false positive rate decreases exponentially. In other words, the longer a wrong decoding path gets, the less likely it gets for the next iteration to be included again as a potential path. The base of the exponential function is the false positive rate, and the exponent corresponds to the length of the invalid decoding path in the binary decoding tree. The false positive rate for a path of length k is computed as Basek, where Base is the single-symbol false positive rate, and k is the number of consecutive symbols in the invalid path. In this regard, the exponential function is used to model the cumulative probability of false positives along the invalid decoding path, thus reflecting a compounding likelihood of pruning as the path length increases.

Optionally, a number of expected wrong decoding paths for a given depth depends on the code's overhead. For a code with zero overhead, or put differently, for a code with a false positive rate of ½, the expected number of wrong decoding paths grows linearly with respect to the length of the input data, which is not a desirable property. For a code with some overhead, or put differently, for a code with a false positive rate lower than ½, the expected number of wrong decoding paths does not grow linearly with increased length of the input data. Moreover, depending on the overhead, the expected number of wrong decoding paths converges to a specific number, regardless of the length of the input data. The expected number of wrong decoding paths during decoding for a given depth and overhead may be computed using the following exemplary formula, given by equation (2)

$${\begin{matrix}{\sum }_{i = 0}^{n} & {2}^{i} ( \frac{1}{2}\end{matrix} )}^{i + 1 + ⌊ \frac{i + m - ( n mod m )}{m} ⌋} \qquad ( 2 )$$

wherein m refers to the interval between the encoded symbols. The interval m relates to the code's overhead. As an example, when m=1, it may be implied that every second encoded symbol is redundant. That is, instead of encoding every source symbol using only one bit, two bits are used (as discussed in example 1). When m=2, it may be implied that for every two bits, a third redundant bit may be added. When m=3, it may be implied that for every three bits, a fourth redundant bit is added, and so on.

As an example, during decoding of the encoded sequence there may be a correct decoding path, the symbols of which may have a different probability to appear present from symbols in a wrong decoding path. That is, the correct decoding path, as well as the sub-paths of the correct decoding path (i.e. segments of the correct path) may always appear to be present in the code. Each symbol of the correct path however may have a chance to give rise to a wrong branch. To figure out the expected number of wrong paths of length n therefore, the expected number of wrong paths of length n may be calculated for each wrong branch of the correct decoding path.

For example, there may be a multi-branch encoding tree comprising the binary tree. The depth of the binary tree may be 4, i.e., a length of the input data may be 4. There may be four branches, namely, Branch A, Branch B, Branch C, Branch D. For a wrong branch, i.e., Branch A, of the correct decoding path at depth 4, and a code with 2× overhead (i.e., m =1), an average number of wrong decoding paths may be

$$( {2}^{0} {( \frac{1}{2} )}^{0 + 1 + 1} ) .$$

For a wrong branch, i.e., Branch B of the correct decoding path at depth 3, an average number of wrong decoding may be

$$( {2}^{1} {( \frac{1}{2} )}^{1 + 1 + 1} ) .$$

For a wrong branch, i.e., Branch C, of the correct decoding path at depth 2, an average number of wrong paths may be

$$( {2}^{2} {( \frac{1}{2} )}^{2 + 1 + 3} ) .$$

Similarly, for a wrong branch, i.e., Branch D, of the correct decoding path at depth 1, an average number of wrong paths may be

$$( {2}^{3} {( \frac{1}{2} )}^{3 + 1 + 4} ) .$$

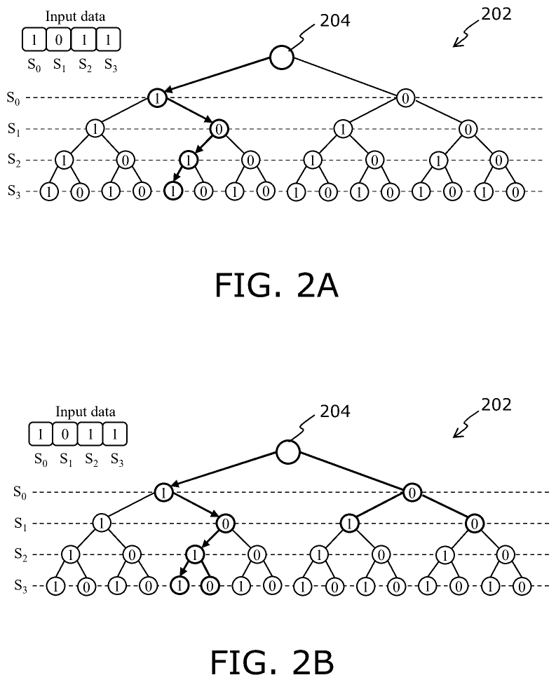

Thereafter, the expected wrong paths are added from each branch to determine the final expected number of wrong paths of length n. This example can be understood in conjunction with FIG. 2.4.

Moreover, the equation (2) can be understood intuitively by dividing said equation (2) into three parts, namely, a first part, a second part, and a third part. In this regard, the first part may be 2′, the second part may be

$${( \frac{1}{2} )}^{i + 1} ,$$

and the third part may be

$$⌊ \frac{i + m - ( n mod m )}{m} ⌋ .$$

Herein, the first part may indicate the number of leaf nodes for a given branch. As an example, a branch (namely, branch A) comprises only one leaf node, so 2⁰=1. As another example, another branch (namely, branch B) comprises two leaf nodes, so 2¹=2, and so on. The second part may indicate false positive rate of a wrong path for a given wrong branch, assuming no overhead (i.e. one bit per encoded symbol). As an example, wrong path in the branch A is made out of only one node, so

$${( \frac{1}{2} )}^{0 + 1} = \frac{1}{2} .$$

As another example, wrong path in the branch B is made out of two nodes, so

$${( \frac{1}{2} )}^{1 + 1} = \frac{1}{4} ,$$

and so on. The third part may compute the number of redundant symbols per path in a branch.

Optionally, the method further comprises:
receiving an overhead percentage value, from a user device, wherein the interval is inversely proportional to the overhead percentage; and
determining the interval, based on the overhead percentage.

Herein, both the overhead percentage value as well as the computational cost of decoding therefore depend on the value chosen for the interval. A larger distance between redundant symbols within the code results in a smaller code overhead, but it also increases the expected number of leaf nodes during decoding. The interval (m) is calculated using a required overhead percentage A, or the overhead percentage given a required interval through an exemplary equation (3),

$$\begin{matrix}Δ = 100 ( 1 - \frac{n}{n + \frac{n}{m}} ) & m = \frac{100}{Δ} - 1\end{matrix} \qquad ( 3 )$$

In this regard, a user device provides an overhead percentage value, which represents the desired level of redundancy in the encoded sequence. This value is received as input by the encoding system. The interval at which redundant symbols are appended to the encoded sequence is calculated based on the provided overhead percentage. The relationship between the interval and the overhead percentage is defined as inversely proportional, meaning a higher overhead percentage results in a shorter interval (more frequent redundancy), and a lower overhead percentage results in a longer interval (less frequent redundancy). The interval decreases as the overhead percentage increases, ensuring that redundancy is added in alignment with the user's desired reliability requirements. A technical effect of the dynamic determination of intervals based on user-defined overhead percentages provides a flexible and efficient way to balance redundancy and performance, ensuring reliable encoding and decoding tailored to specific system requirements.

Optionally, the method further comprises:
receiving an interval value, from a user device; and
determining an overhead percentage value, based on the interval value and a total number of the plurality of source symbols.

Herein, a user device provides an interval value, representing the frequency at which redundant symbols are appended to the encoded sequence. Using the received interval value and the total number of source symbols in the sequence, the system calculates the overhead percentage. This is achieved using the formula:

$$Overhead percentage = \frac{Number of redundant symbols}{Total number of Source symbols} \times 100$$

where the number of redundant symbols is derived from the total number of source symbols and the interval value.

In this regard, the interval value specifies how often redundant symbols are added to the encoded sequence. The proportion of redundancy introduced into the encoded sequence, expressed as a percentage of the total number of source symbols. The interval value determines the overhead percentage; shorter intervals (more frequent redundancy) that result in higher overhead percentages, while longer intervals produce lower overhead percentages. A technical effect of the aforementioned feature is that a flexible mechanism is provided to control redundancy, thus enabling efficient and reliable encoding tailored to diverse system needs.

In an embodiment, at the step of recurringly appending the redundant symbol, the method further comprises:
initializing a first chain header for a primary chain using a first nonce, and a second chain header for a secondary chain using a second nonce;
processing each source symbol sequentially from amongst the plurality of source symbols to generate corresponding encoded symbol in the primary chain, wherein the encoded symbol comprises one bit per source symbol;
processing a given source symbol from amongst the plurality of source symbols at the interval to generate an additional encoded symbol in the secondary chain;
appending the encoded symbol from the secondary chain at the interval; and
evaluating the branching condition based on combined outputs of the primary chain and the secondary chain at each interval,
   wherein at the step of decoding the encoded sequence, the method further comprises:
evaluating the branching condition based on a combination of a first output of the primary chain and a second output of the secondary chain at each step of the interval; and
iteratively pruning the invalid decoding paths using the first output and the second output.

In this regard, the redundant symbol is assigned to some encoded symbols by using at least two chains, namely, the primary chain and the secondary chain. In an instance, when the plurality of source symbols represent binary values, in the primary chain, every encoded symbol uses up one bit. In other words, the primary chain is the same length as a length of the plurality of source symbols. In contrast, the secondary chain, encodes each source symbol, but only every m-th encoded symbol is retained, while others are discarded. In another instance, instead of storing all encoded symbols from the first chain and only every m-th encoded symbol from the second chain, each chain stores only every N-th encoded symbol, wherein N is a number of chains computed. As an example, the first chain may store the first encoded symbol, the Nth one, the 2Nth one, and so on. The second chain may store the second encoded symbol the N+1-th encoded symbol, the 2(N+1)-th encoded and so on.

As long as N+1 is collected out of the N chains (i.e. one redundant chain, but with a unique nonce, for one of the indices), the input data can be reconstructed.

That way, during decoding of the encoded sequence, an every of half the available leaf nodes are pruned at every m-th step. During decoding, a branching condition is expressed by an exemplary expression (4):

$${e}_{0 , i}^{′} = {e}_{0 , i} ⋀ ( ¬ m \_steps \vert ( {e}_{1 , i}^{′} = {e}_{1 , i} ⋀ m \_steps ) ) \qquad ( 4 )$$

Herein, the branching condition is used to determine whether a symbol gets accepted as a candidate path. In other words, for a candidate path to be accepted, at every m-th step, a presence of both

$${e}_{0 , i}^{′} = {e}_{0 , i}$$

$$and$$

$${e}_{1 , i}^{′} = {e}_{1 , i}$$

are checked, while at every other step, only a presence of

$${e}_{0 , i}^{′} = {e}_{0 , i}$$

is schecked.

In a third example, there may be an algorithm to perform information chaining using the primary chain and the secondary chain. The primary chain and the secondary chain are initialized with their respective chain headers, i.e., the first chain header and the second chain header, using two distinct nonces, i.e., the first nonce and the second nonce. Sequentially each source symbol is processed to generate corresponding encoded symbols in the primary chain, with each encoded symbol comprising one bit per source symbol. For every predefined interval (for example, every m-th source symbol), the same source symbol is processed to generate an additional encoded symbol in the secondary chain. The additional encoded symbols from the secondary chain are appended at the predefined interval to the encoded sequence. Moreover, during decoding, the branching condition for potential decoding paths is evaluated based on the combined outputs of the primary and secondary chains.

Moreover, performing information chaining in the aforementioned manner is beneficial for exemplary scenarios, for example, networks with many-to-one mappings, like in peer-to-peer networks. In such an exemplary scenario, a given node may try to download separate fragments of a file from many peers. Herein, it may be useful to download a unique chain per peer, wherein the unique chain may comprise a unique nonce. Hence, two peers may not be able to accidentally send same fragment.

A technical effect of the aforementioned feature is that it enhances error correction by systematically incorporating redundancy while optimizing computational and storage resources through a dynamic branching condition based on combined outputs.

In another embodiment, at the step of recurringly appending the redundant symbol, the method further comprises:
initializing a third chain header using a nonce;
encoding each source symbol from amongst the plurality of source symbols into a single bit per source symbol, and updating the third chain header; and
at the intervals, appending the redundant symbol to the encoded sequence,
   wherein at the step of decoding the encoded sequence, the method further comprises:
evaluating the correct decoding path by validating each branch based on the encoded symbol and corresponding redundant symbol; and
pruning the invalid decoding paths by using the redundant symbol at the intervals.

In this regard, the redundant symbol is assigned to some encoded symbols by using one chain. Herein, every source symbol is encoded using one bit, while every encoded symbols at every m-th step is encoded using two bits. In a fourth example, there may be an algorithm to perform information chaining using a single chain. The third chain header is initialized using a nonce. Each source symbol from the input data is encoded into a single bit, while updating the third chain header iteratively to ensure sequential dependency. At every m-th symbol, an additional redundant symbol is computed and appended to the encoded sequence. During decoding, each branch of the decoding tree is validated by combining the outputs of the encoded symbol and the corresponding redundant symbol. Invalid decoding paths are pruned iteratively using the combined validation, reducing computational complexity and improving decoding accuracy. This algorithm may be provided by exemplary rust examples (i.e., Rust Example 3 for encoding data and Rust Example 4 for decoding data) in the APPENDIX.

A technical effect of the aforementioned feature is that it enhances decoding reliability by systematically validating and pruning incorrect paths, thereby ensuring accurate and efficient reconstruction of the input data.

In yet another embodiment, at the step of recurringly appending the redundant symbol, the method further comprises:
initializing a fourth chain header using a at least a nonce;
determine at least one interval for appending the redundant symbol based on at least one statistical property of the input data; and
appending the redundant symbol at the at least one interval,
   wherein at the step of decoding the encoded sequence, the method further comprises:
evaluating the branching conditions and validate the correct decoding path from amongst the plurality of decoding paths, based on the appended redundant symbols; and
iteratively pruning the invalid decoding paths at the at least one interval.

In this regard, a single bit is assigned to every encoded symbol, and a redundant one-bit symbol is encoded at every m-th step. The fourth chain header may be initialized using a nonce and predefined parameters. Herein, for encoding the input data, the input data, the nonce and the m-value are required. These parameters may include configurations or constraints specific to the input data or the encoding process. The interval (m) for appending redundant symbols is dynamically determined based on one or more statistical properties of the input data, such as distribution, variance, or entropy. This ensures that, upon encountering a redundant symbol during decoding, the correct decoding path can be identified. This effectively prunes, on average, half of the candidate paths for each redundant symbol.

For example, an m-value may be selected based on an expected packet loss rate. While decoding the input data, 1 percent to 2 percent of erasures of the encoded sequence may be expected. When m=40, that means an overhead percentage value of 2.5 percent may be added to the encoded sequence, which means erasures ranging from 1 percent to 2 percent may be tolerated. Conversely, a higher packet loss rate may be expected (for example, 10 percent of the encoded sequence). When m=20, that means an overhead percentage value of 12.5 percent may be added to the encoded sequence, which means erasures up to 10 percent may be tolerated.

In a fifth example, there may be an algorithm to perform information chaining using a single bit. The fourth chain header may be initialized using at least a nonce. The interval (m) for appending redundant symbols may be dynamically determined based on at least one statistical property of the input data. The redundant symbols are appended to the encoded sequence at the m-intervals. During decoding, branching conditions may be evaluated using the appended redundant symbols to validate the correct decoding path among the plurality of paths. Moreover, the invalid decoding paths may be pruned iteratively at each interval, guided by the appended redundant symbols and predefined probabilistic rules.

Optionally, when the encoded sequence comprises at least one erased encoded symbol, at the step of decoding the encoded sequence, the method further comprises:
computing a Boolean vector that indicates at least one index position of the at least one encoded symbol in the encoded sequence that is erased, wherein a Boolean value of TRUE represents the at least one encoded symbol that is erased, and a Boolean value of FALSE represents that the at least one encoded symbol is present in the encoded sequence; and
for each of the at least one erased encoded symbol in the encoded sequence:
   generating at least one branch for at least one possible candidate symbols to account for absence of the encoded symbol that corresponds to the at least one erased encoded symbol at a given index position; and
   adding the at least one branch to a set of potential decoding paths.

Herein, the Boolean vector indicates index positions of erased encoded symbols within the encoded sequence. Herein, each Boolean value represents a status of corresponding encoded symbol, wherein TRUE indicates an erased encoded symbol, and FALSE indicates a present encoded symbol. For each erased encoded symbol identified by the Boolean vector, at least one branch is generated for possible candidate symbols to account for the absence of the erased encoded symbol. In other words, a branch is created per erasure. In an instance, in binary information chaining, the branch of the multi-branch decoding tree that comprises the binary tree, comprises 2 children. In another instance, in symbol information chaining (for example, byte information chaining), the branch of the multi-branch decoding tree comprises 256 children.

Moreover, newly generated branches are added to the existing set of potential decoding paths, ensuring the possibility of reconstructing the erased symbol. Subsequently, during decoding, these additional branches allow exploring alternative paths. Such exploration compensates for missing information and preserving the ability to reconstruct the source sequence. For example, there may be 100 packets, wherein each packet has an index. Assuming that it is known how many packets were supposed to be received, it may be determined how many packets out of the 100 packets may be lost. Using the indices of the packets, it may be known exactly which encoded symbols were lost. Hence, 100 data packets may be sent at a particular address, but a receiver at that particular address may collect 98 packets out of the 100 packets. This means that 2 packets got lost, and it may be known exactly which encoded symbols were lost. Through this information, the Boolean vector may be calculated by decoding the encoded sequence. Moreover, the aforementioned algorithm may be provided by an exemplary rust example (i.e., Rust example 7) in the APPENDIX. Furthermore, the algorithm for encoding and decoding of the input data in probabilistic symbol chaining may be provided by exemplary rust examples (i.e., Rust Example 5 for encoding the input data and Rust Example 6 for decoding the input data, respectively) in the APPENDIX.

A technical effect is that due to the introduction of additional decoding branches to account for erased encoded symbols, it enables accurate reconstruction of the symbol source sequence by systematically exploring potential decoding paths and compensating for missing data.

The present disclosure also relates to the second aspect as described above. Various embodiments and variants disclosed above, with respect to the aforementioned first aspect, apply mutatis mutandis to the second aspect.

Herein, the at least one processor could be implemented as any one of: a microprocessor, a microcontroller, or a controller. As an example, the at least one processor could be implemented as an application-specific integrated circuit (AISC) chip or a reduced instruction set computer (RISC) chip.

### APPENDIX

### Rust Examples

It will be appreciated that all the rust examples 1, 2, 3, 4, 5, 6, and 7use xxh3 as their hash function. Moreover, any hash function or pseudorandom number generator could have been used. The following dependences need to be included first

```
[ package ]
name = “ booklet_code ”
version = “ 0.1.0 ”
edition = “ 2021 ”
[ dependencies ]
xxh3 = “ 0.1.1 ”
1. Rust example 1: Message Encoding in Probabilistic Binary Chaining
(Prototype)
pub fn state_change <T: Into <u64 >>( chain_header : u64 , s: T) ->
u64 {
xxh3 :: hash64_with_seed (& chain_header . to_le_bytes ( ) , s. into ( ))
3 }
pub fn encode_proto ( input : &[ bool ], nonce : u64 ) -> (Vec <bool >,
u64 )
{
let mut code : Vec <bool > = Vec :: new ( );
let mut chain_header = nonce ;
input . iter ( ). for_each (|s| {
chain_header = state_change ( chain_header , *s);
let e_0 : bool = chain_header & 1 == 1;
let e_1 : bool = ( chain_header >> 1) & 1 == 1;
code . extend ( vec ![ e_0 , e_1 ]);
});
(code, chain_header )
}
2. Rust example 2: Breadth-first Decoding in Probabilistic Binary
Chaining (Prototype)
use std : : collections : : VecDeque ;
pub fn decode_proto (code: &Vec <bool >, nonce: u64, final_header:
u64) -> Option <Vec <bool >> {
let mut potential_paths : VecDeque <( Vec <bool >, u64 )> = VecDeque
:: new ( );
potential_paths . push_back (( Vec :: new ( ) , nonce ));
  let symbol_set = [false , true ];
  for e in encoded_symbols . chunks (2) {
  let mut branches : VecDeque < ( Vec <bool >, u64 ) > = VecDeque ::
    new ( );
  while let Some (( path , previous_chain_header )) =
    potential_paths . pop_front ( ) {
    for & s_prime in & symbol_set {
      let chain_header = state_change (
        previous_chain_header , s_prime );
      let e_0_prime: bool = chain_header & 1 == 1;
      let e_1_prime: bool = ( chain_header >> 1) & 1 == 1;
      if e == [ e_0_prime , e_1_prime ] {
        let mut new_path = path . clone ( );
        new_path . push ( s_prime );
        branches.push_back((new_path,
      chain_header));
      }
    }
  }
  potential_paths = branches ;
}
// Find the leaf node with the correct header
for (potential_path , potential_header) in potential_paths {
  if potential_header == final_header {
    return Some ( path );
  }
}
None
}
3. Rust example 3: Message Encoding in Probabilistic Binary Chaining
pub fn encode ( input : &[ bool ], nonce : u64 , m: usize ) -> (Vec <bool
>, u64 ) {
  let mut code: Vec <bool > = Vec :: new ( );
  let mut chain_header : u64 = nonce ;
  input . iter ( ). enumerate ( ). for_each (|(i, s) | {
    chain_header = state_change ( chain_header , *s);
    let e: bool = chain_header & 1 == 1;
    code . push (e);
    if (i + 1) % m = = 0 {
      let redundant_e : bool = ( chain_header >> 1) & 1 ==
    1;
      code. push ( redundant_e );
    }
  });
  (code, chain_header)
}
4. Rust example 4: Breadth-first Decoding in Probabilistic Binary
Chaining
use std : : collections : : VecDeque ;
pub fn decode (
  code: &Vec <bool >,
  nonce : u64 ,
  final_header : u64 ,
  n: usize ,
  m: usize ,
) -> Option <Vec <bool >> {
  let mut potential_paths : VecDeque <( Vec <bool >, u64 )> =
  VecDeque: new ( );
  potential_paths . push_back (( Vec :: new ( ) , nonce ));
  let symbol_set = [false , true ];
  let mut position : usize = 0;
  for i in 0.. n {
    let e = code[ position ];
    let is_redundant_e = if (i + 1) % m == 0;
    let redundant_e = if is_redundant_bit {
      position += 1;
      code [position]
  } else {
    false
  };
  let mut branches : VecDeque <( Vec <bool >, u64 )> =
VecDeque : : new ( );
  while let Some (( path , previous_chain_headers )) =
    potential_paths . pop_front ( ) {
    for &s_prime in &symbol_set {
      let chain_header = state_change (
        previous_chain_headers , s_prime );
      let e_prime : bool = chain_header & 1 == 1;
      let redundant_e_prime : bool = ( chain_header
    >> 1) & 1 == 1;
      if e_prime == e && (! is_redundant_bit | | (
      redundant_e_prime == redundant_e)){
      let mut new_path = path . clone ( );
      new_path . push ( s_prime );
      branches.push_back((new_path,
    chain_header));
      }
    }
  }
  potential_paths = branches ;
  position += 1;
}
// Find the leaf node with the correct header
for (potential_path , potential_header) in potential_paths {
  if potential_header == final_header {
    return Some (potential_path );
  }
}
  None
}
5. Rust example 5: Message Encoding in Probabilistic Symbol Chaining
pub fn encode ( input : &[ u8 ], nonce : u64 , m: usize ) -> (Vec <u8>,
u64 )
  {
  let mut code: Vec <u8 > = Vec :: new ( );
  let mut chain_header : u64 = nonce ;
  input . iter ( ). enumerate ( ). for_each (|(i, s) | {
    chain_header = state_change ( chain_header , *s);
    let e: u8 = (chain_header & 0xFF) as u8;
    code. push (e);
    if (i + 1) % m == 0 {
      let redundant_e : u8 = ((chain_header >> 8) & 0xFF)
      as u8;
      code. push ( redundant_e );
    }
  });
  ( code, chain_header )
}
6. Rust example 6: Breadth-first Decoding in Probabilistic Symbol
Chaining
use std : : collections : : VecDeque ;
pub fn decode_v3 (
  code: &Vec <u8>,
  nonce : u64 ,
  final_header : u64 ,
  n: usize,
  m: usize ,
) -> Option <Vec <u8 >> {
  let mut potential_paths : VecDeque <( Vec <u8 >, u64 )> =
  VecDeque :: new ( );
  potential_paths . push_back (( Vec :: new ( ) , nonce ));
  let symbol_set : Vec <u8> = (0.. = 255). collect ( );
  let mut position: usize = 0;
  for i in 0.. n{
    let e = code[position];
    let is_redundant_bit = (i+1)%m == 0;
    let redundant_e = if is_redundant_bit {
      position +=1;
      code [position]
    } else {
      0
    };
  let mut branches : VecDeque <( Vec <u8 >, u64 )> = VecDeque
:: new ( );
  while let Some (( path , previous_chain_headers )) =
    potential_paths . pop_front ( ) {
    for &s_prime in &symbol_set {
      let chain_header = state_change (
        previous_chain_headers , s_prime );
      let e_prime : u8 = ((chain_header >> 8) & 0xFF) as
    u8;
      if e_prime == e && (!is_redundant_bit | |
        redundant_e_prime = redundant_e)) {
        let mut new_path = path . clone ( );
        new_path . push ( s_prime );
        branches . push_back (( new_path ,
      chain_header ));
      }
    }
  }
  potential_paths = branches ;
  position += 1;
  }
  // Find the leaf node with the correct header
  for (potential_path , potential_header) in potential_paths {
    if potential_headers == final_header {
      return Some ( potential_path );
  }
}
None
}
7. Rust example 7: Breadth-first Decoding with Erasures in
Probabilistic Binary Chaining
use std : : collections : : VecDeque ;
pub fn decode (
  code: &Vec <bool >,
  nonce : u64 ,
  final_header : u64 ,
  n: usize,
  m: usize ,
  holes : Vec <bool >,
) -> Option <Vec <bool >> {
  let mut potential_paths : VecDeque <( Vec <bool >, u64 )> =
VecDeque
    :: new ( );
  potential_paths . push_back (( Vec :: new ( ) , nonce ));
  let symbol_set = [false , true ];
  let mut position : usize = 0;
  for i in 0.. n{
    let e = code [position];
    let hole = holes [position];
    let is_redundant_bit = (i+1)%m == 0;
    let (redundant_e, redundant_hole) = if is_redundant_bit{
      position +=1;
      (code [position], holes[position])
    } else {
      (false, false)
    };
    let mut branches : VecDeque <( Vec <bool >, u64 )> =
  VecDeque : : new ( );
  while let Some (( path , previous_chain_headers )) =
    potential_paths . pop_front ( ) {
    for & s_prime in &symbol_set {
      let chain_header = state_change (
        previous_chain_headers , s_prime );
      let e_prime : bool = chain_header & 1 == 1;
      let redundant_e_prime: bool = (chain_header >> 1) &
    1 == 1;
      let present : bool = ( e_prime == e) | hole ;
      let redundant: bool = (redundant_e_prime ==
redundant_e) | | redundant_hole;
      if present && (!is_redundant_bit | | redundant) {
        let mut new_path = path . clone ( );
        new_path . push (s_prime);
      branches . push_back (( new_path , chain_header ));
      }
    }
  }
  potential_paths = branches ;
  position += 1
}
// Find the leaf node with the correct header
for (potential_path , potential_header) in potential_paths {
  if potential_headers == final_header {
    return Some ( potential path );
  }
}
None
}
```

### DETAILED DESCRIPTION OF THE DRAWINGS

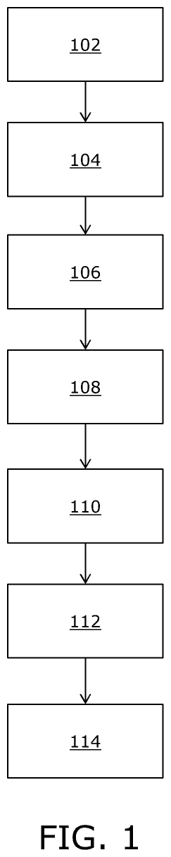

Referring to FIG. 1, illustrated is a flowchart depicting steps of a method for encoding and probabilistically decoding data, in accordance with an embodiment of the present disclosure. At step 102, an input data comprising a plurality of source symbols is received, wherein each source symbol represents a binary value or a multi-bit value. At step 104, an encoded sequence is initialized to an empty state. At step 106, a chain header is initialized by setting a value of the chain header to a nonce. At step 108, each source symbol is iteratively encoded sequentially from amongst the plurality of source symbols to generate the encoded sequence, by: updating the chain header, based on a preceding chain header and current source symbol; generating an encoded symbol for each source symbol, based on the updated chain header, wherein the encoded symbol represents a binary value or a multi-bit value; and updating a state of the encoded sequence by storing the encoded symbol at a given index position within the encoded sequence, wherein the encoded sequence is initialized with unassigned values. At step 110, a final chain header is generated after iterative encoding of all source symbols in the plurality of source symbols. At step 112, the encoded sequence, and the final chain header are transmitted. At step 114, the encoded sequence is decoded by: reconstructing candidate source symbol sequences through probabilistic traversal of potential decoding paths in a multi-branch decoding tree, wherein each node corresponds to the given source symbol; and determining a correct decoding path from amongst a plurality of decoding paths by iteratively pruning invalid decoding paths based on at least predefined probabilistic rules, wherein the correct decoding path comprises the candidate source symbol sequence that aligns with the plurality of source symbols and produces a final chain header that matches the final chain header comprised in the encoding metadata.

The aforementioned steps are only illustrative, and other alternatives can also be provided where one or more steps are added, one or more steps are removed, or one or more steps are provided in a different sequence without departing from the scope of the claims herein.

Referring to FIG. 2A, there is illustrated a decoding process of a multi-branch encoding tree comprising a binary tree 202, in accordance with an embodiment of the present disclosure. In this regard, the input data comprises a plurality of source symbols representing binary values. The input data may, for example, be 1011, at bit index positions s₀, s₁, s₂, and s₃ respectively. In the binary tree, a root 204 is initialized with a nonce as the chain header. A depth of the binary tree 202 corresponds to a length of the input data, wherein each level of the depth represents a bit index position of each source symbol from amongst the plurality of source symbols. Hence, the depth of the binary tree 202 is 4. The decoding process starts from the root 204. At each iteration, it is checked whether symbol zero or one is able to fulfil a branching condition for a given bit index position, and gradually grow the binary tree. For instance, left branches of the binary tree represent a zero for the given bit index position, and right branches of the binary tree represent a one for a given bit index position, then the actual source symbol sequence can be imagined to be a path within that binary tree.

Referring to FIG. 2B, there is illustrated a decoding process of the binary tree 202 due to false positives, in accordance with an embodiment of the present disclosure. In this regard, the decoding process branches off into many paths. Herein, the path that starts from the root 204 and ends at the bit index position s₃ represents the correct decoding path (i.e., a branch on a left side of the root 204, namely, a left branch), while the path that starts from the root 204 and ends at the bit index position s₁ represents the wrong decoding path (i.e., a branch on a right side of the root 204, namely, a right branch). In this regard, to determine whether the first symbol of the input data was zero or one, the left branch will have a 1.0 probability to be present in an encoded sequence of the input data. The right branch, which was not inserted during decoding, has a 0.25 probability to appear as present (because of the probability for false positive hits). If both symbols happen to appear as present during the lookup, then both the symbols are accepted as candidate source symbols.

During the next iteration in FIG. 2B, the branching probability of the correct decoding path will be 1.0 for right branch (zero) and 0.25 for the left branch (one). The branching probabilities of the wrong path will both be 0.25 again. Note that the false positive rate of a single wrong symbol is 0.25, but the false positive rate for consecutive wrong symbols is 0.25^{k}, where k represents the length of a wrong path within the binary tree. As 0.25^{k} quickly converges to zero with increasing k, the further we diverge from the correct path, the more likely it gets for the wrong paths to reach dead-ends (i.e. to have both left and right branches not present in the code). Reaching a dead-end means that the path taken was a wrong path, as the correct path terminates only after reaching depth n (i.e., the length of the input data).

FIGS. 2A-B are merely examples, which should not unduly limit the scope of the claims herein. A person skilled in the art will recognize many variations, alternatives, and modifications of embodiments of the present disclosure.

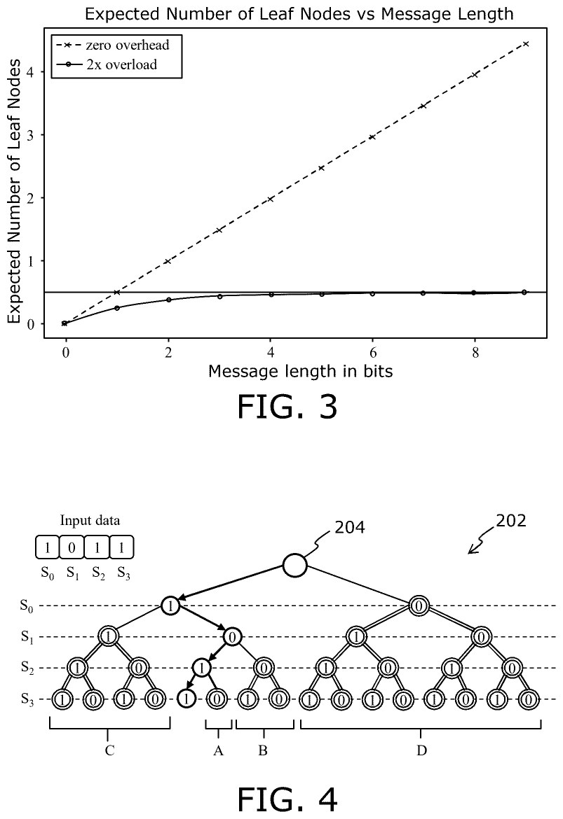

Referring to FIG. 3, there is illustrated a graphical representation of a relationship between code overhead, expected number of lead nodes, and a length of input data, in accordance with an embodiment of the present disclosure. Herein, X-axis represents the length of input data in bits, and Y-axis represents the expected number of lead nodes. The graph is plotted for 2× overhead (as shown by a solid line with dots), and zero overhead (as shown by a dashed line with crosses). It is observed while the expected number of leaf nodes for the code with zero overhead increases linearly with increased message length, the one with 2× overhead converges to 0.5 wrong paths with increased message length.

FIG. 3 is merely an example, which should not unduly limit the scope of the claims herein. A person skilled in the art will recognize many variations, alternatives, and modifications of embodiments of the present disclosure.

Referring to FIG. 4, there is illustrated a depiction of wrong branches for a given correct path of FIG. 2A, in accordance with an embodiment of the present disclosure. In FIG. 4, there may be four branches, namely, Branch A, Branch B, Branch C, and Branch D, for the given correct path. During decoding there will be a correct decoding path, the symbols of which will have a different probability to appear present from symbols in a wrong path. That is, the correct decoding path, as well as sub-paths of the correct decoding path (i.e. segments of the correct decoding path) will always appear to be present in the encoded sequence. Each symbol of the correct decoding path however has a chance to give rise to a wrong branch. To determine the expected number of wrong paths of length n therefore, the expected number of wrong paths of length n is to be calculated for each wrong branch of the correct decoding path.

FIG. 4 is merely an example, which should not unduly limit the scope of the claims herein. A person skilled in the art will recognize many variations, alternatives, and modifications of embodiments of the present disclosure.

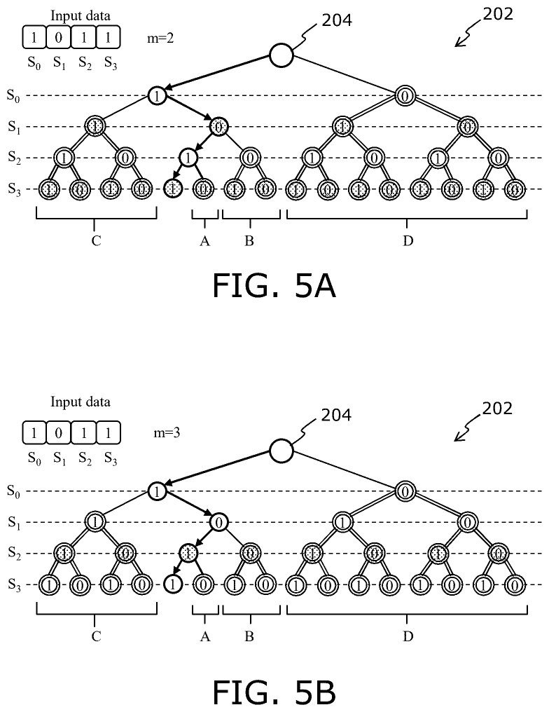

Referring to FIGS. 5A and 5B, there is illustrated a depiction of wrong branches for a given correct decoding path of a binary tree of FIG. 2A, in accordance with an embodiment of the present disclosure. In FIG. 5A, instead of assigning two bits to every encoded symbol, a redundant symbol is assigned only to every second encoded symbol, thus effectively decreasing the code overhead from 2× to 33.3 percent of the encoded sequence. In FIG. 5B, a redundant bit symbol is assigned to every third encoded symbol, which effectively decrease the overhead from 33.3 percent to 24.99 percent.

FIGS. 5A-B are merely examples, which should not unduly limit the scope of the claims herein. A person skilled in the art will recognize many variations, alternatives, and modifications of embodiments of the present disclosure.

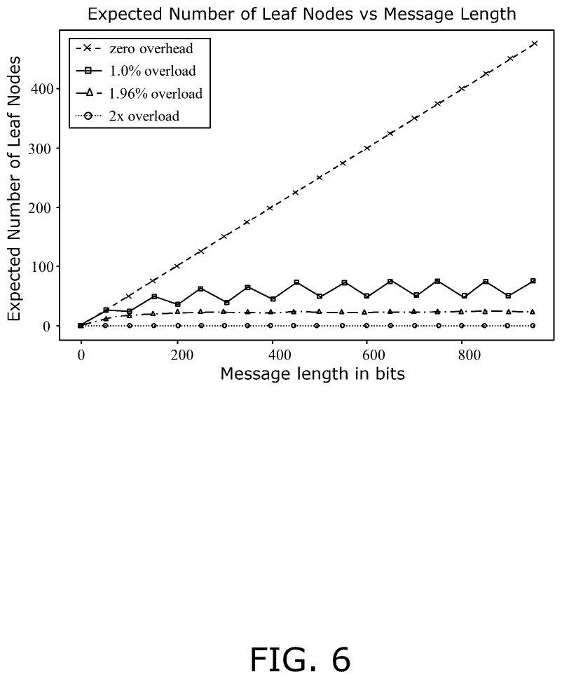

Referring to FIG. 6, there is a graphical representation of a relationship between various code overheads, expected number of leaf nodes and length of the input data, in accordance with an embodiment of the present disclosure. Herein, X-axis represents the length of input data in bits, and Y-axis represents the expected number of lead nodes. The graph is plotted for 2× overhead (as shown by a solid line with dots), 1.96 percent overhead (as shown by a solid line with triangles), 1.0% percent overhead (as shown by a solid line with square), and zero overhead (as shown by a dashed line with crosses). For an encoded sequence with m=1, i.e. a 2× overhead, the expected number of leaf nodes was almost zero, independent of a length of the input data. For an encoded sequence with zero overhead, the expected number of leaf nodes grew proportionally with the message length. When a higher value of m is chosen, for example, m=50, that is, by setting the code overhead to 1.96%, decoding of the encoded sequence is performed independent of the length of the input data, while still having on average only up to 50 leaf nodes at any given moment during decoding. If m=100, that is, if the code has an overhead of 1%, the input data is decoded, while still having on average only up to 100 leaf nodes at any given moment during decoding. Note that for encoded sequences with m>1 the expected number of leaf nodes does not gradually converge to a given value like for m=1, but converges to an oscillation with m being the upper bound of the oscillation.

FIG. 6 is merely an example, which should not unduly limit the scope of the claims herein. A person skilled in the art will recognize many variations, alternatives, and modifications of embodiments of the present disclosure.

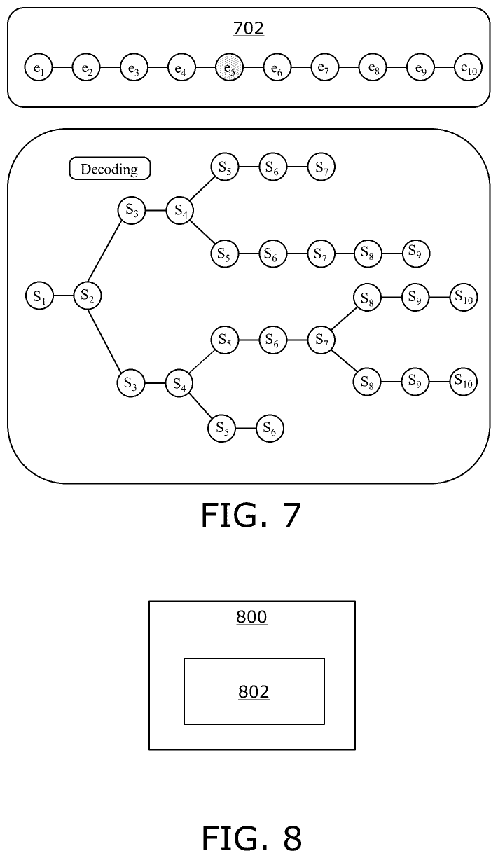

Referring to FIG. 7, there is shown a sequential diagram for erasure in encoded sequence, in accordance with an embodiment of the present disclosure. The encoded sequence 702 comprises a plurality of encoded symbols, namely, e₀, e₁, e₂, . . . , e₁₀. The at least one encoded symbol in the encoded sequence that is erased is e₅. While decoding, there is a branching at e₂, hence two potential paths after e₂ has to be accepted and then accept both branches at e₄ for each of the two potential paths, and so on.

FIG. 7 is merely an example, which should not unduly limit the scope of the claims herein. A person skilled in the art will recognize many variations, alternatives, and modifications of embodiments of the present disclosure.

Referring to FIG. 8, there is illustrated a block diagram of a system 800 for encoding and probabilistically decoding data, in accordance with an embodiment of the present disclosure. The system 800 comprises at least one processor (depicted as a processor 802). The processor is configured to carry out processing steps of the second aspect.

FIG. 8 is merely an example, which should not unduly limit the scope of the claims herein. A person skilled in the art will recognize many variations, alternatives, and modifications of embodiments of the present disclosure.

1. A method for encoding and probabilistically decoding data, the method comprising:
receiving an input data comprising a plurality of source symbols, wherein each source symbol represents a binary value or a multi-bit value;
initializing an encoded sequence to an empty state;
initializing at least one chain header by setting a value of the at least one chain header to a nonce;
iteratively encoding each source symbol sequentially from amongst the plurality of source symbols to generate the encoded sequence, by:
updating the at least one chain header, based on a preceding chain header and a current source symbol;
generating an encoded symbol for each source symbol, based on the updated chain header, wherein the encoded symbol represents a binary value or a multi-bit value; and
updating a state of the encoded sequence by storing the encoded symbol at a given index position within the encoded sequence, wherein the encoded sequence is initialized with unassigned values;
generating a final chain header after iterative encoding of all source symbols in the plurality of source symbols;
transmitting the encoded sequence, and the final chain header; and
decoding the encoded sequence by:
reconstructing candidate source symbol sequences through probabilistic traversal of potential decoding paths in a multi-branch decoding tree, wherein each node corresponds to the given source symbol; and
determining a correct decoding path from amongst a plurality of decoding paths by iteratively pruning invalid decoding paths, based on at least predefined probabilistic rules,
wherein the correct decoding path comprises the candidate source symbol sequence that aligns with the plurality of source symbols and produces a final chain header that matches the final chain header of the encoded sequence.

2. The method of claim 1, wherein the multi-branch decoding tree comprises a binary tree, the step of decoding emulates a breadth-first traversal of the binary tree, wherein the binary tree is characterized by:
a root initialized with a nonce as the at least one chain header;
a depth corresponding to a length of the input data, wherein each level of the depth represents a bit index position of each source symbol from amongst the plurality of source symbols;
a branching condition to grow the binary tree iteratively, wherein the branching condition is determined when a predefined probabilistic criterion for branching at a given bit index position is met, wherein the predefined probabilistic criterion is satisfied when a value of a candidate symbol in the candidate symbol sequence produces a candidate encoded symbol that matches a corresponding encoding symbol of the ended sequence; and
a plurality of branches based on false positive matches, wherein each of the plurality of branches is pruned iteratively during traversal to converge towards the correct decoding path.

3. The method of claim 2, wherein the false positive match comprises a decoding path from amongst the plurality of decoding paths that appears present during the step of decoding the encoded sequence, but was not utilized at the step of iteratively encoding each source symbol sequentially from amongst the plurality of source symbols to generate the corresponding encoded symbol in the encoded sequence.

4. The method of claim 2, wherein a rate of the false positive matches for consecutive candidate source symbol in the candidate source symbol sequence that forms the invalid decoding path is an exponential function, wherein a base of the exponential function corresponds to a false positive rate and an exponent corresponds to a length of the invalid decoding path within the binary tree.

5. The method of claim 1, wherein at the step of iteratively encoding each source symbol sequentially from amongst the plurality of source symbols to generate the encoded sequence, the method further comprises recurringly appending a redundant symbol at an interval of at least one encoded symbol comprised in the encoded sequence.

6. The method of claim 5, wherein a probability of the correct decoding path being identified lies is based on the false positive rate, and a probability of the invalid decoding path being selected is based on the interval of at least one encoded symbol.

7. The method of claim 5, wherein at the step of recurringly appending the redundant symbol, the method further comprises:
initializing a first chain header for a primary chain using a first nonce, and a second chain header for a secondary chain using a second nonce;
processing each source symbol sequentially from amongst the plurality of source symbols to generate corresponding encoded symbol in the primary chain, wherein the encoded symbol comprises one bit per source symbol;
processing a given source symbol from amongst the plurality of source symbols at the interval to generate an additional encoded symbol in the secondary chain;
appending the encoded symbol from the secondary chain at the interval; and
evaluating the branching condition based on combined outputs of the primary chain and the secondary chain at each interval,
wherein at the step of decoding the encoded sequence, the method further comprises:
evaluating the branching condition based on a combination of a first output of the primary chain and a second output of the secondary chain at each step of the interval; and
iteratively pruning the invalid decoding paths using the first output and the second output.

8. The method of claim 5, wherein at the step of recurringly appending the redundant symbol, the method further comprises:
initializing a third chain header using a nonce;
encoding each source symbol from amongst the plurality of source symbols into a single bit per source symbol, and updating the third chain header; and
at the intervals, appending the redundant symbol to the encoded sequence, wherein at the step of decoding the encoded sequence, the method further comprises:
evaluating the correct decoding path by validating each branch based on the encoded symbol and corresponding redundant symbol; and
pruning the invalid decoding paths by using the redundant symbol at the intervals.

9. The method of claim 5, wherein at the step of recurringly appending the redundant symbol, the method further comprises:
initializing a fourth chain header using at least a nonce;
determine at least one interval for appending the redundant symbol based on at least one statistical property of the input data; and
appending the redundant symbol at the at least one interval,
wherein at the step of decoding the encoded sequence, the method further comprises:
evaluating the branching conditions and validate the correct decoding path from amongst the plurality of decoding paths, based on the appended redundant symbols; and
iteratively pruning the invalid decoding paths at the at least one interval.

10. The method of claim 6, further comprising:
receiving an overhead percentage value, from a user device, wherein the interval is inversely proportional to the overhead percentage; and
determining the interval, based on the overhead percentage.

11. The method of claim 6, further comprising:
receiving an interval value, from a user device; and
determining an overhead percentage value, based on the interval value and a total number of the plurality of source symbols.

12. The method of claim 1, wherein when the encoded sequence comprises at least one erased encoded symbol, at the step of decoding the encoded sequence, the method further comprises:
computing a Boolean vector that indicates at least one index position of the at least one encoded symbol in the encoded sequence that is erased, wherein a Boolean value of TRUE represents the at least one encoded symbol that is erased, and a Boolean value of FALSE represents that the at least one encoded symbol is present in the encoded sequence; and
for each of the at least one erased encoded symbol in the encoded sequence:
generating at least one branch for at least one possible candidate symbols to account for absence of the encoded symbol that corresponds to the at least one erased encoded symbol at a given index position; and
adding the at least one branch to a set of potential decoding paths.

13. The method of claim 1, wherein the nonce comprises at least one of: an empty state, a counter, a random number, a random number generated via a public key.

14. The method of claim 1, wherein the at least one chain header is updated by at least one of: a hash function, a random number generator, a mathematical function, a Boolean operation, a cryptographic technique, a linear transformation, a state transition based on a given source symbol from amongst the plurality of source symbols, a neural network model.

15. The method of claim 1, wherein the plurality of decoding paths lies in a range of total number of the plurality of source symbols to an exponential function of two with an exponent of the total number of the plurality of source symbols.

16. The method of claim 1, wherein the multi-bit value comprises a byte.

17. A system for encoding and probabilistically decoding data, the system comprising at least one processor configured to:
receive an input data comprising a plurality of source symbols, wherein each source symbol represents a binary value or a multi-bit value;
initialize an encoded sequence to an empty state;
initialize at least one chain header by setting a value of the at least one chain header to a nonce;
iteratively encode each source symbol sequentially from amongst the plurality of source symbols to generate the encoded sequence, wherein the at least one processor is configured to:
update the at least one chain header, based on a preceding chain header and a current source symbol;
generate an encoded symbol for each source symbol, based on the updated chain header, wherein the encoded symbol represents a binary value or a multi-bit value; and
update a state of the encoded sequence by storing the encoded symbol at a given index position within the encoded sequence, wherein the encoded sequence is initialized with unassigned values;
generate a final chain header after iterative encoding of all source symbols in the plurality of source symbols;
transmit the encoded sequence, and the final chain header; and
decode the encoded sequence, wherein the at least one processor is configured to:
reconstruct candidate source symbol sequences through probabilistic traversal of potential decoding paths in a multi-branch decoding tree, wherein each node corresponds to the given source symbol; and
determine a correct decoding path from amongst a plurality of decoding paths by iteratively pruning invalid decoding paths, based on at least predefined probabilistic rules,
wherein the correct decoding path comprises the candidate source symbol sequence that aligns with the plurality of source symbols and produces a final chain header that matches the final chain header of the encoding sequence.
